(19) United States
(12) Patent Application Publication
(10) Pub. No.: US 2010/0013354 A1
(43) Pub. Date: Jan. 21, 2010

(54) ADJUSTING DEVICE WITH HIGH POSITION RESOLUTION, EVEN IN THE NANO-OR SUBNANOMETER RANGE

(75) Inventors: Harry Marth, Waldbronn (DE); Rong Liang, Waldbronn (DE); Patrick Pertsch, Hermsdorf (DE)

Correspondence Address: BODNER & O'ROURKE, LLP, 425 BROADHOLLOW ROAD, SUITE 108, MELVILLE, NY, 11747, US

(73) Assignee: Physik Instrumente (PI) GmbH & Co. KG, Karlsruhe (DE)

(21) Appl. No.: 12/309,990

(22) PCT Filed: Aug. 13, 2007
(86) PCT No.: PCT/EP2007/058359

§ 371 Date: Jun. 23, 2009

(30) Foreign Application Priority Data
Aug. 14, 2006 (DE) 10 2006 038 011.8
Sep. 20, 2006 (DE) 10 2006 044 285.7

(51) Int. Cl. H01L 41/09; H02N 2/04

(52) U.S. Cl. 310/317; 310/328

(57) ABSTRACT

The invention relates to an adjusting device with high position resolution, even in the nano- or subnanometer range and a regulating distance of a few micrometers up to several hundred millimeters, wherein PZT-solid state actuators in a closed-loop control circuit are used for the main control direction, the positions thereof being determined by high resolution sensors and the PZT-solid state actuators are in connection with a platform (2) via joints. For the compensation of position errors occurring perpendicular to the individual position, additional actuators (5) on the basis of piezoelectric single crystals are intended according to the invention. The single crystals are actuated according to stored values in an error table, wherein the respective control value results as a function of the main control axis, however with reversed gradient signs, and the additional actuators are connected to the adjusting device platform by a correcting plate (4).

The invention relates to an adjusting device with a high position resolution, even in the nano- or subnanometer range, and a travel of a few micrometers up to several hundred millimeters, wherein PZT solid-state actuators operated in a closed loop are used for the main operating directions, the respective position of which can be determined by means of high-resolution sensors, and wherein further the PZT solid-state actuators communicate via joints with a platform, according to the preamble of patent claim 1.

Nanopositioners on the basis of solid-state actuators are known. In this respect, nanopositioners are adjusting units, which have a correcting range of a few micrometers up to several millimeters. The position resolution is within the nanometer or subnanometer range, respectively.

In order to avoid friction and suppress play, spring joint guides are, in many cases, used for the positioner units. In an eroding step, the spring joints may here be formed as flexural joints from a metal block.

Due to manufacturing tolerances of the components, but also due to inaccuracies during the assembly, the guiding accuracy of the spring joints is limited. In prior art products, typical position errors perpendicular to the operating direction are in the range of about 5 nm to 10 nm per 100 μm of the travel.

The market requirements increasingly focus. on nanopositioners with a guiding accuracy<2 nm per several 100 μm of the movement. To realize these guiding accuracies, many attempts were made to generate prestressing forces by additional mechanical elements, such as prestressing screws, wedges or the like, so as to increase the guiding accuracies. Mechanical means of this type shown, for example, in DE 198 26 984 A1 do not lead to reproducible results, however, and do not satisfy the requirements in view of the necessary long-term stability.

Multi-axis positioners having up to six degrees of freedom of the company Physik Instrumente (PI) GmbH & Co. KG allow the measurement of undesired parasitic motions, whereby those axes of such multi-axis positioners, that do not define an operating direction, may be used for the active error correction.

Solid-state actuators on the basis of a PZT-ceramic have great expansion ranges necessary to realize large travels, but are subject to undesired hysteresis and creep behavior. To realize the required high resolution it is, therefore, necessary that each active axis is provided with a high-resolution sensor. Moreover, the actuators are operated in a closed loop. However, such a technology causes very high system costs, and it is hardly realizable on the market if only few main operating directions are needed.

As to the prior art, reference is made to the printed publications EP 0833208 A2, DE 3786955 T2, U.S. Pat. No. 5,241,235 A, U.S. Pat. No. 6,310,342 B1, DE 10296462 T5, US 2006/0097162 A1 and DE 102004002199 A1. Document EP 0833208 A2 thereof relates to an adjusting device with a position resolution even in the nano- or subnanometer range. For the main operating directions, actuators operated in the closed loop are used, the position of which can be determined by means of sensors. The actuators communicate with a platform. Additional actuators serve the compensation of errors caused, for example, by a varying thickness of the semiconductor substrate to be processed. Thus, there is no compensation of the error that is caused by position errors of the adjusting device in the main operating direction. In addition, the arrangement of the additional actuators according to EP 0833208 A2 is to provide a basically additional adjusting possibility in a third, namely the Z-axis.

Based on the foregoing it is, therefore, the object of the invention to provide a further developed adjusting device with a high position resolution in the nano- or subnanometer range and a travel of a few micrometers up to several millimeters, which allows the compensation of parasitic position errors not occurring in the actual main operating direction without additional high-resolution sensors, and wherein no separate position error controllers are necessary for controlling the positioner.

The solution to the object of the invention is achieved with an adjusting device according to the combination of features defined in patent claim 1. Claim 5 relates to a method for operating such an adjusting device.

The dependent claims represent at least expedient embodiments and advancements.

According to the invention, additional actuators on the basis of piezoelectric monocrystals are employed to compensate parasitic position errors which occur, for example, perpendicular to the respective main operating direction. Although such monocrystals, such as quartz or lithium niobate, have a substantially smaller piezoelectric effect as compared to known PZT-ceramics, they are not subject to hysteresis or an undesired creep behavior.

These additional actuators on the basis of piezoelectric monocrystals are actuated according to the values stored in an error table, wherein the respective control value is obtained as a function of the main operating axes, however, subject to sign reversal. The additional actuators are rigidly connected to the adjusting device platform by a correction plate.

As the additional actuators are only required to compensate those position errors that have values of up to several hundred nanometers, it is possible to configure the error correction module very compact and to integrate it either in the adjusting device or, optionally, arrange it externally in series with the actual adjuster as a retrofit unit.

For the commonly performed actuation of the adjusting device, a correction value for the additional actuators as a function of the main operating axes is determined from the error table, and is then converted into a correcting movement subject to a sign reversal.

Thus, in accordance with the method for operating the adjusting device according to the invention, the respective position errors deviating from, e.g. perpendicular to the main operating directions are initially determined in a calibrating step as a function of the actual values in the main operating directions X, Y and are stored in an error table Zₙ=f(X,Y). In accordance with the respective set value for the main operating directions X, Y a correction value for the additional actuators is then determined from the error table and, subject to a sign reversal, is converted to the required correcting movement.

Due to the open-loop control there are no regulation deviations in the axes to be corrected. If few main operating axes are concerned, the additional actuators may be readily controlled by the provided controllers.

In an embodiment of the invention the error tables may be-adapted to reference objects or reference surfaces measured by the user. Altogether, the implementation of the invention brings about a cost reduction for the fabrication of the mechanical components and the assembly of the adjusting device, as a result of admissible greater tolerances and due to the fact that, in contrast to other cases, no sensors are necessary.

Thus, the invention makes it possible that position errors into those directions, that are not the main operating directions, tend to zero. That is, incorrect guiding, deformations caused by mass displacements, or position errors caused by similar sources are compensated, namely without the use of high-resolution and expensive sensors.

The invention is typically applied in scan tables with main operating directions X and Y. The crosstalk in the XY-plane (Y-error during motion in X-direction and vice versa) can be determined, and corrected by the main actuators. As to the remaining degrees of freedom (Z perpendicular to XY and the tilts), so far neither actuators nor sensors have become known to perform corrections. For a great number of applications, especially in microscopy, it is necessary to keep the focus distance in the Z-direction constant with nanometer accuracy during the scan movement. Here, to correct errors of the Z-axis, the Z-error is determined as a function of the X- and Y-directions and is compensated.

In a Z-axis focusing unit, the main operating axis is provided in the Z-direction. There is, however, the necessity to keep position errors in the XY-plane small. In such a case, a two-dimensional correcting element in the form of a shearing element is used for the XY-plane. This shearing element is controlled on the basis of error tables X-error=f(Z) and Y-error=f(Z).

The error mapping for XY-scanner applications may be realized as follows. Initially, a test run with a freely choosable number m x n of measuring points takes place in the XY-direction. For example, 10X and 12Y points are traveled to, so that a total of 120 measuring points are obtained. The software employed contains an interpolation algorithm, which calculates the Z-correction value from the closest sampling points for any optional commanded XY-position. In the case, where the gradients between adjacent sampling points in the test scan performed are too large, the number of sampling points is increased.

For a correction, for example, of two axes, errors per axis to be corrected are determined for the one main operating direction Z, e.g. 10X+12Y=22 measuring points. Here, too, the software interpolates, separately according to the axis to be corrected, between the closest sampling points for any optional commanded Z-position. The memory requirement in this modified embodiment is smaller. By a direct communication between the piezo-controller and the error measurement during the calibration the above-described procedure may be performed fully automatically. There is no need for additional hardware. According to the invention only the free amplifiers for the actuators, or those provided anyhow, also control the additional correction actuators.

As was described, a central idea of the invention relates to the use of linear piezoelectric actuators, preferably made of lithium niobate or other monocrystalline, hysteresis-free materials, for the correction of errors.

This represents another possible application. For measurements by means of AFM-devices (atomic force microscopy) height profiles can be determined in the nano- and subnanometer range. If the sensor tip is in the proximity zone of or in contact with the object of measurement, a cantilever beam made of silicon is subjected to flexural stresses, and the reflected laser beam generates an electric signal on a PSD-element (positive sensitive device). A PID-controller generates from the sensor signal a controlled variable, and drives via a high-voltage amplifier a piezoelectric actuator in such a way that the sensor tip has a constant distance to the surface or exerts a constant pressure force onto the surface, respectively. By this compensation method the PSD sensor signal is kept approximately constant, even if the measuring surface moves horizontally, namely in terms of a scan movement. At the output of the controller, or at the output of the high-voltage amplifier, respectively, an electric signal is available, which is to be proportional with respect to the height of the surface structure of the measured object. Due to non-linearities of the piezoelectric actuator, however, such a method results in clear signal distortions and, thus, in height measurement errors. As the required travels of the piezoelectric actuator in AFM measurements are in the range of 0.5 to 1 μm, it is possible, in accordance with the central idea of the invention in respect of the correction actuators used, to improve the accuracies for these correcting ranges. The provided, very good linear expansion behavior of piezoelectric actuators made of monocrystalline materials in combination with high dynamic properties results in a definitive improvement for AFM measurements. Complicated linearizations by an inverse hysteresis simulation, which were required so far, are not necessary.

The invention shall be explained in more detail below by means of an embodiment and with the aid of the figures.

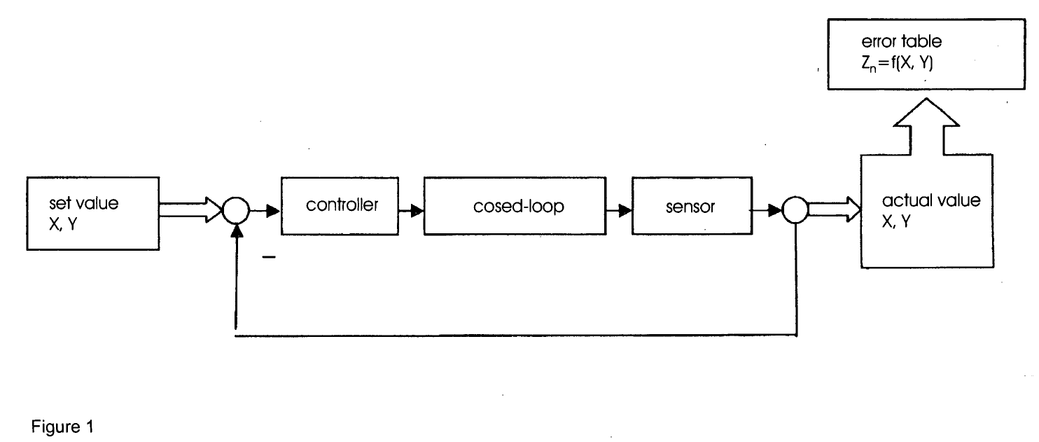

FIG. 1 shows a block diagram of the actuation of an XY-positioner and the determination of position errors in the Z-direction as a function of the set value vector;

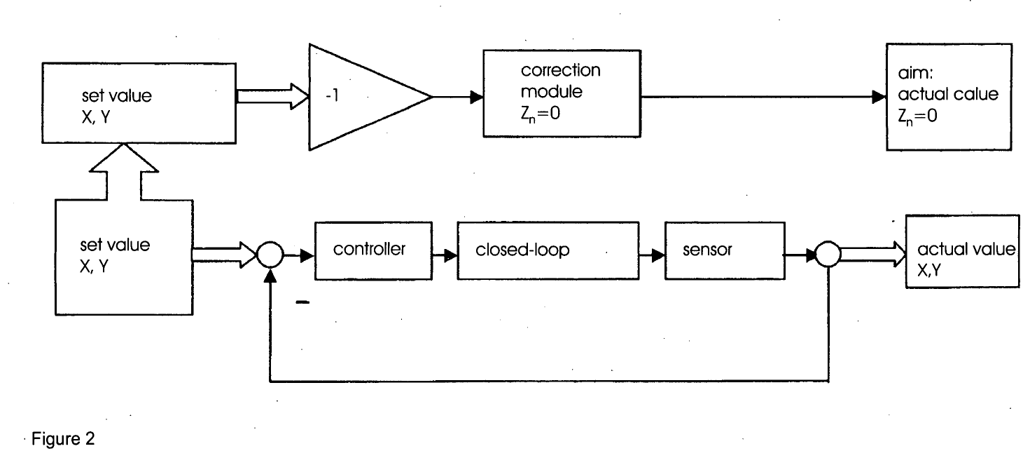

FIG. 2 shows a block diagram of the actuation of an XY-positioner in the main operating directions (X, Y) and of a correction module in the Z-direction, with the aim to minimize the Z-error;

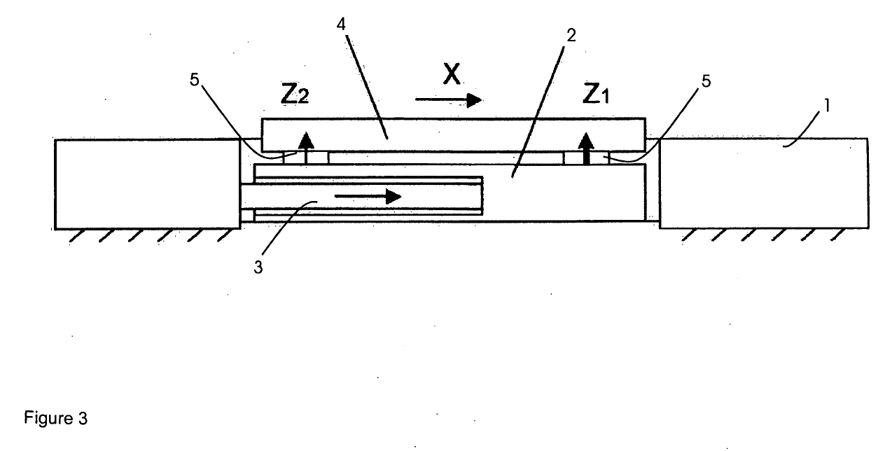

FIG. 3 shows a schematic sectional view of a positioner, comprising an integrated correction module for a main operating direction X and two axes to be corrected Z₁ and Z₂;

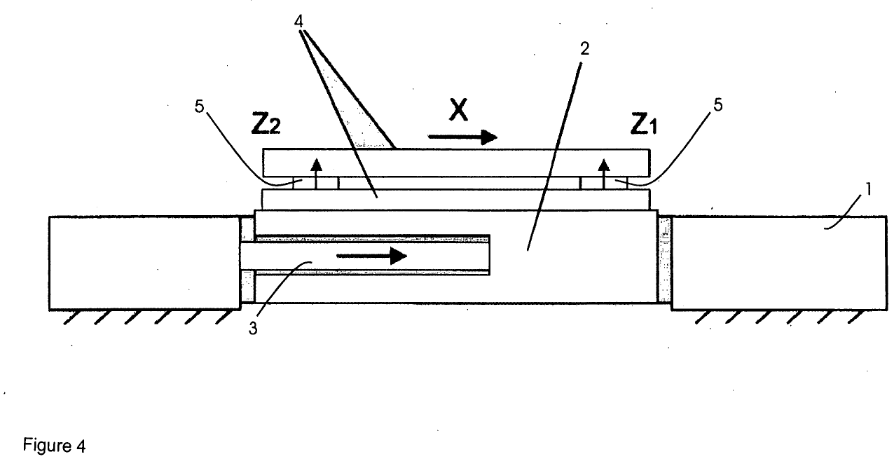

FIG. 4 shows a positioner according to the invention, comprising an external correction module for a main operating direction X and two axes to be corrected Z₁ and Z₂ for retrofitting purposes; and

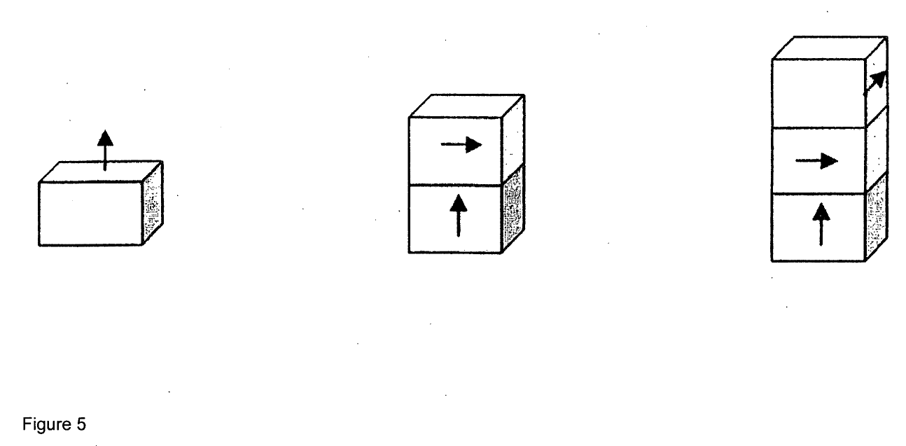

FIG. 5 shows a schematic representation of correction actuators having one, two and three degrees of freedom in one element as a combination of thickness and shear converter, and having up to five degrees of freedom by multiple use.

In one embodiment only the main operating directions (number equal to N) of the positioners are operated with PZT solid-state actuators and high-resolution sensors in the closed loop.

The position errors with the maximum number 6−N are determined in a calibrating step and stored in an error table within the controller, which is provided anyhow.

Moreover, a maximum number 6−N of additional correction actuators are used, the travel ranges of which are sufficiently large to compensate position errors up to some hundred nanometers.

Suited materials for the additional actuators are preferably piezoelectric monocrystals, such as quartz or lithium niobate, the piezoelectric effect of which is substantially smaller as compared to that of PZT-ceramics, but which are not subjected to an undesired hysteresis or creep behavior.

Due to the small travel ranges, the structure of these additional elements as error correction module can be very compact, and they can either be mechanically integrated in the positioner or, optionally, are externally connected to the adjuster.

For actuating the positioner, a correction value for the error correction module as a function of the main operating axes is determined from the previously defined error table, and is converted to a correcting movement subject to sign reversal.

FIG. 1 illustrates how, during the actuation of an XY-positioner, position errors in the Z-direction can be determined and are stored in an error table as a function of the set value vector.

During the operation of the XY-positioner according to FIG. 2, with an actuation in the main operating directions X, Y and with a correction module in the Z-direction, it is desired to minimize the Z-error. To this end, a value according to the predefined set value X, Y is read out from the error table, which, subject to a sign reversal, is then applied to the respective additional actuators, namely with the aim to eliminate undesired errors, e.g. tilts in the Z-direction.

According to the representations shown in FIG. 3 and 4 a mobile platform 2 with a main operating direction X is arranged by means of joints in a frame 1. At least one PZT-actuator 3 is provided to drive the platform 2.

In the representation according to FIG. 3 the positioner shown therein is supplemented with an integrated correction plate 4, which serves to eliminate errors in the Z-direction.

To this end, additional actuators 5 are positioned between the correction plate 4 and the platform 2, which are made of piezoelectric monocrystals. These additional actuators 5 are driven according to the values from the error table (see FIG. 2), with the aim to eliminate the Z-error.

The positioner according to FIG. 4, with the external correction module comprising two parallel and spaced-apart correction plates 4, is designed as a retrofit unit. According to this configuration, the correction module comprised of the two plates 4, with additional actuators 5 positioned therebetween, can be connected to the platform 2 or arranged on the same subsequently.

To perform corrections also in several degrees of freedom, it is possible to design a combined correction element as thickness and shear converter, which is shown in the schematic representation according to FIG. 5.

In another possible application, e.g. an XY-tube scanner, it is likewise provided to arrange a separate Z-correction module. Tube scanners being a component part of a microscope perform a motion in the XY-plane. Due to unavoidable flexures, an arc-shaped Z-error occurs. In this case, the sample to be tested could be placed onto a Z-compensator so as to eliminate the error in the Z-direction according to the invention, so that the relative distance between the sensor tip and the sample can be kept constant. Only by this measure can the user distinguish by means of the measured result whether the error is possibly caused by the scanner, or whether the surface of the sample is, in effect, uneven. An analogous positive effect can be achieved, if the Z-compensator moves the measuring head with the tube scanner into the Z-direction in a compensating manner, while the sample is stationary relative thereto.

### LIST OF REFERENCE NUMBERS

1 frame
2 platform
3 PZT-piezoelectric actuator
4 correction plate
5 additional actuator (correction actuator)

1. Adjusting device with a high position resolution, even in the nano- or subnanometer range, and a travel of a few micrometers up to several hundred millimeters, wherein PZT solid-state actuators operated in a closed loop are used for the main operating directions, the respective position of which can be determined by means of high-resolution sensors, and wherein further the PZT solid-state actuators communicate via joints with a platform,
characterized in that
for the compensation of position errors occurring externally of the respective main operating direction additional actuators on the basis of piezoelectric monocrystals are provided, which are actuated according to the values stored in an error table, wherein the respective control value is obtained as a function of the main operating axes, however subject to sign reversal, and the additional actuators are rigidly connected to the adjusting device platform by a correction plate.

2. Adjusting device according to claim 1,
characterized in that
a correction module on the basis of two spaced-apart correction plates and correction actuators positioned therebetween is arranged on the platform in a retrofittable manner.

3. Adjusting device according to claim 1,
characterized in that
the correction actuators have one or more degrees of freedom.

4. Adjusting device according to claim 1,
characterized in that
the additional actuators for the correction of errors are made of creep- and hysteresis-free piezoelectric materials, specifically quartz or lithium niobate monocrystals.

5. Method for operating an adjusting device according to claim 1,
characterized in that
the respective position errors deviating from the main operating directions are determined in a calibrating step as a function of the actual values in the main operating directions X, Y and are stored in an error table Zₙ=f(X,Y), and that in accordance with the respective set value for the main operating directions (X, Y) a correction value for the additional actuators is determined from the error table and, subject to a sign reversal, is converted to a correcting movement.

6. Adjusting device according to claim 2,
characterized in that
the correction actuators have one or more degrees of freedom.

7. Adjusting device according to claim 2,
characterized in that
the additional actuators for the correction of errors are made of creep- and hysteresis-free piezoelectric materials, specifically quartz or lithium niobate monocrystals.

8. Adjusting device according to claim 3,
characterized in that
the additional actuators for the correction of errors are made of creep- and hysteresis-free piezoelectric materials, specifically quartz or lithium niobate monocrystals.

9. Method for operating an adjusting device according to claim 2,
characterized in that
the respective position errors deviating from the main operating directions are determined in a calibrating step as a function of the actual values in the main operating directions X, Y and are stored in an error table Zₙ=f(X,Y), and that in accordance with the respective set value for the main operating directions (X, Y) a correction value for the additional actuators is determined from the error table and, subject to a sign reversal, is converted to a correcting movement.

10. Method for operating an adjusting device according to claim 3,
characterized in that
the respective position errors deviating from the main operating directions are determined in a calibrating step as a function of the actual values in the main operating directions X, Y and are stored in an error table Zₙ=f(X,Y), and that in accordance with the respective set value for the main operating directions (X, Y) a correction value for the additional actuators is determined from the error table and, subject to a sign reversal, is converted to a correcting movement.

11. Method for operating an adjusting device according to claim 4,
characterized in that
the respective position errors deviating from the main operating directions are determined in a calibrating step as a function of the actual values in the main operating directions X, Y and are stored in an error table Zₙ=f(X,Y), and that in accordance with the respective set value for the main operating directions (X, Y) a correction value for the additional actuators is determined from the error table and, subject to a sign reversal, is converted to a correcting movement.
